(19) United States
(12) Patent Application Publication
(10) Pub. No.: US 2012/0070918 A1
(43) Pub. Date: Mar. 22, 2012

(54) METHOD OF MANUFACTURING SEMICONDUCTOR DEVICE

(75) Inventor: Osamu Fujita, Tokyo (JP)

(73) Assignee: ELPIDA MEMORY, INC., Tokyo (JP)

(21) Appl. No.: 13/232,600

(22) Filed: Sep. 14, 2011

(30) Foreign Application Priority Data
Sep. 16, 2010 (JP) 2010-208460

(51) Int. Cl. H01L 21/66

(52) U.S. Cl. 438/17; 257/E21.531

(57) ABSTRACT

A method of manufacturing a semiconductor device may include, but is not limited to the following processes. First and second grooves are formed in a semiconductor substrate having a first surface. The first and second grooves have substantially the same vertical dimension. The first surface has first and second regions surrounded by the first and second grooves, respectively. An actual resistance value of the semiconductor substrate between a first point on the first region and a second point on the second region is measured. The vertical dimension of the first and second grooves is calculated with reference to the actual resistance value.

### BACKGROUND OF THE INVENTION

1. Field of the Invention

The present invention relates to a method of manufacturing a semiconductor device. Particularly, the present invention relates to a method of manufacturing a semiconductor device, which includes a process of measuring the depth of a groove formed in a semiconductor substrate.

Priority is claimed on Japanese Patent Application No. 2010-208460, filed Sep. 16, 2010, the content of which is incorporated herein by reference.

2. Description of the Related Art

A method of related art of manufacturing a semiconductor device includes a process of forming a hole or groove in a semiconductor substrate. For example, when a device isolation region surrounding an active region including an active element such as transistor is formed in a silicon substrate, the silicon substrate is etched to form a groove therein. In this case, the silicon substrate is etched without providing a stopper layer for defining the depth of the groove. For this reason, the depth of the groove is generally controlled by controlling an etching processing time.

Technically, it is more difficult to control the depth of groove by controlling the etching condition than by using the stopper layer. However, it has been able to precisely control, based on technical experience, the depth of the groove for forming the device isolation region.

Additionally, when a hole or groove is formed by a manufacturing method of related art, the depth of the hole or groove is measured to determine a condition for forming the hole or groove and to conform whether the hole or groove is formed in a predetermined size. Generally, AFM (Atomic Force Microscope), SCD (Spectra Critical Dimension), and the like have been used as a method of measuring the depth of a hole or groove.

As a device that measures the size and shape of a microscopic structure over a semiconductor substrate, for example, Japanese Patent Laid-Open Publication No. 2004-64006 discloses a non-destructive measuring device that includes: a measuring unit configured to scan a main surface of a semiconductor substrate by irradiating to the main surface, a plurality of electron beams at a predetermined irradiation angle and at different irradiation energies, and the measuring unit being configured to measure a substrate current generated in the semiconductor substrate; a storing unit configured to store a value of the substrate current measured; and an estimating unit configured to estimate the microscopic structure based on the relationship between the substrate currents and the irradiation energies.

As a method of non-destructively measuring an over-etching amount for an etching process of forming a wiring hole, Japanese Patent Laid-Open Publication No. 2005-150340 discloses a method of manufacturing a semiconductor device, which includes an etching condition calculating process. In the etching condition calculating process, the depth of a hole formed in a region including an underlying layer and the depth of a hole formed in a region not including the underlying layer are measured and compared. Thus, the etching conditions of these holes are determined to form holes with adequate depths.

Additionally, Japanese Patent Laid-Open Publication No. H10-154737 discloses a method of manufacturing a semiconductor device, in which the resistance of a layer on a test pattern region is measured by a four probe method to test a buried condition of a hole in a product chip region.

However, the methods of the related art of measuring the depth of a hole or groove cannot be applied to when the hole or groove has a large depth and small width, such as when a semiconductor chip including a through electrode penetrating a semiconductor substrate is formed in order to manufacture a semiconductor device including multi-layered chips.

The through electrode of the semiconductor chip is formed by forming a groove in a semiconductor substrate and filling the groove with a conductive material. Generally, the through electrode has a cylindrical shape, the diameter of 10 to 30 μm, and the depth of approximately 50 μm. Generally, a depth of a groove for forming a device isolation region is approximately 0.3 μm. Accordingly, the groove for forming the through hole is much deeper than that for forming the device isolation region. However, the width of the groove for forming the through electrode is sufficiently large. Accordingly, the AFM and the SCD can be used to measure the depth of the groove for forming the through electrode, similarly to when the depth of the groove for forming the device isolation region is measured.

However, when a circular insulating film functioning as a barrier film for preventing thermal diffusion is buried in a semiconductor substrate so as to surround a through electrode, such as when a through electrode made of copper is formed, a circular groove is formed in the semiconductor substrate. Then, the circular groove is filled with an insulator to form the insulating film. Then, the through hole is formed in the region inside the insulating film in plan view. The circular groove for forming the insulating film has the same depth as of the through electrode, and therefore is very deep. Meanwhile, the width of the circular groove is small to achieve miniaturization of the semiconductor device,

It has been difficult to non-destructively measure the depth of such a hole or groove with a large depth and a small width by the manufacturing method of the related art. In other words, when the AFM is used to measure the depth of such a hole or groove with a large depth and a small width, a probe cannot reach a bottom of the hole or groove, thereby making the measurement difficult.

When the SCD is used to measure the depth of such a hole or groove with a large depth and a small width, a beam hardly reaches a bottom of the groove, thereby making the measurement difficult. Particularly when the groove has a curved side surface, such as the circular groove for forming the insulating film, a beam hardly reaches a bottom of the groove compared to the case of a straight groove with the same depth and width, thereby making the measurement by the SCD more difficult.

Additionally, it is more technically difficult to control the depth of a groove with a large depth and a small width than to control the depth of a groove with a small depth and a large width. A groove in a semiconductor substrate, such as the circular groove for forming the insulating film surrounding the through electrode, is formed by etching the semiconductor substrate without providing a stopper layer for defining the depth of the groove. Accordingly, it is technically difficult to control the depth of the groove formed in the semiconductor substrate.

Further, it is important to confirm whether the depth of the formed groove is within an allowable range, especially when the circular groove surrounding the through electrode is formed, since the depth of the circular groove affects the characteristics of the multi-layered chip. Therefore, it has been necessary to confirm whether the depth of the circular groove for forming the insulating film surrounding the through electrode is within an allowable range.

### SUMMARY

In one embodiment, a method of manufacturing a semiconductor device may include, but is not limited to the following processes. First and second grooves are formed in a semiconductor substrate having a first surface. The first and second grooves have substantially the same vertical dimension. The first surface has first and second regions surrounded by the first and second grooves, respectively. An actual resistance value of the semiconductor substrate between a first point on the first region and a second point on the second region is measured. The vertical dimension of the first and second grooves is calculated with reference to the actual resistance value.

In another embodiment, a method of manufacturing a semiconductor device may include, but is not limited to the following processes. At least one groove is formed in a semiconductor substrate having a first surface. The first surface has first and second regions separated from each other by the at least one groove. A reference resistance value of the semiconductor substrate between first and second points on the first region is measured. An actual resistance value of the semiconductor substrate between a third point on the first region and a fourth point on the second region is measured. A difference between the reference resistance value and the actual resistance value is calculated. A vertical dimension of the at least one groove is calculated with reference to the difference.

In another embodiment, a method may include, but is not limited to the following processes. An actual resistance value of a semiconductor substrate between first and second points is measured. The first and second points are positioned on first and second regions of a first surface of the semiconductor substrate, respectively. The first and second regions are surrounded by first and second grooves in the semiconductor substrate, respectively. The first and second grooves have substantially the same vertical dimension. The vertical dimension of the first and second grooves is calculated with reference to the actual resistance value.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 10 illustrate a process flow indicative of a method of manufacturing a semiconductor device according to a first embodiment of the present invention;

FIG. 11 is a flowchart illustrating the method according to the first embodiment; and

FIG. 12 is a graph illustrating the relationship between an actual resistance value measured by the method of the first embodiment and the depth of a groove.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

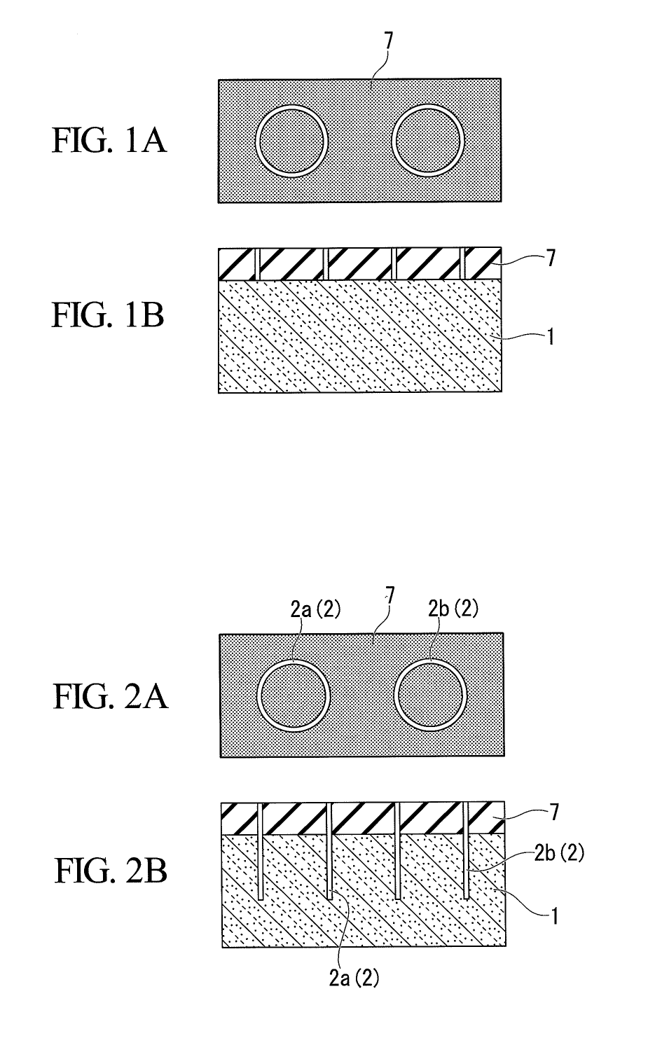

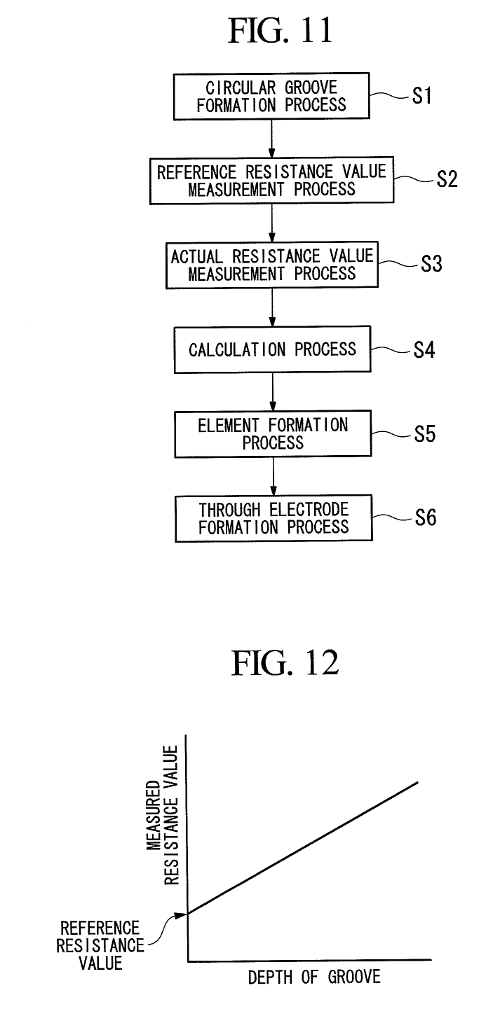

FIGS. 1A to 10 illustrate a process flow indicative of a method of manufacturing a semiconductor device according to a first embodiment of the present invention. For simplification of explanations, FIGS. 1A to 5B illustrate only a region in which two of multiple circular grooves are formed. FIGS. 1A, 2A, 3A, 4A, and 5A are plan views. FIGS. 1B, 2B, 3B, 4B, and 5B are cross-sectional views corresponding to FIGS. 1A, 2A, 3A, 4A, and 5A, respectively. FIGS. 6 to 10 are cross-sectional views illustrating only a region in which one of the two grooves shown in FIGS. 1A to 5B is formed. FIG. 11 is a flowchart illustrating a method of manufacturing a semiconductor device according to the first embodiment.

As an example of a manufacturing method of the present invention, a method of manufacturing a semiconductor device including a multi-layered chip is explained in the first embodiment. The manufacturing method of the first embodiment includes: a process of forming a semiconductor chip 10 shown in FIG. 10; and a process of stacking multiple semiconductor chips 10 to form a multi-layered chip.

Hereinafter, the semiconductor chip 10 formed by the manufacturing method shown in FIG. 11 is explained. As shown in FIG. 10, the semiconductor chip 10 includes: a semiconductor substrate 1; multiple grooves 2 in the semiconductor substrate 1; an insulating film 3 filing each of the circular grooves 2; an active element (not shown) and a wire 4 which are disposed over the semiconductor substrate 1; a through electrode 5 penetrating the semiconductor substrate 1; and bumps 6a and 6b electrically coupled to the through electrode 5 in order to electrically couple the semiconductor chip 10 to another semiconductor chip.

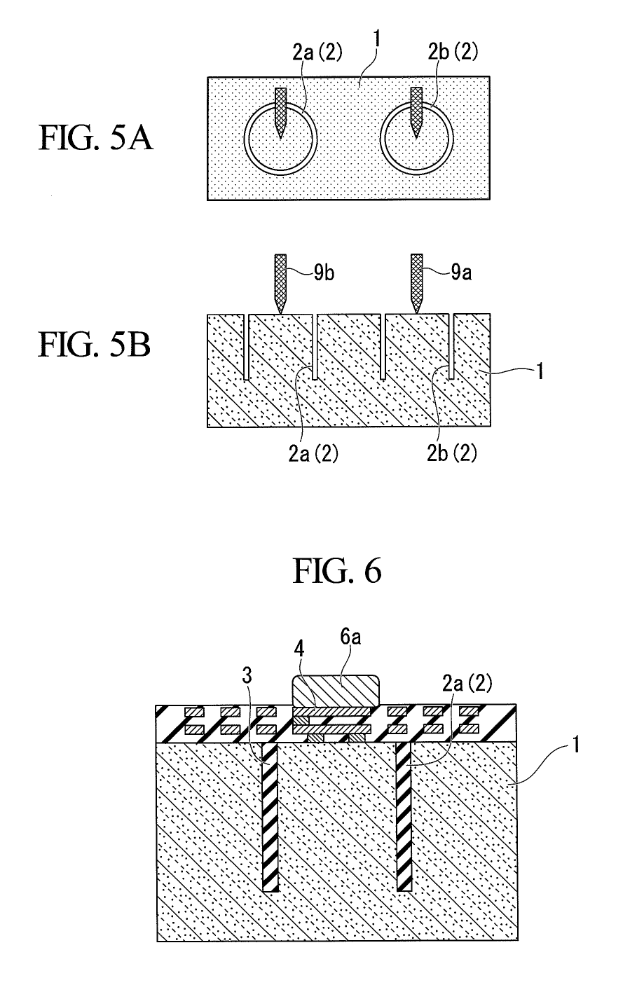

The semiconductor substrate 1 is made of a silicon substrate. The through electrode 5 is made of a conductive material, such as copper. The insulating film 3 functions as a bather film for preventing thermal diffusion. As shown in FIG. 5A, the groove 2 has a circular shape in plan view, and thus the insulating film 3 filling the groove 2 has also a circular shape in plan view. However, the shape of the groove 2 is not limited thereto, the groove 2 may have a polygonal shape as long as the shape is closed in plan view.

The semiconductor chip 10 functions as a DRAM (Dynamic Random Access Memory). Although not shown, the semiconductor chip 10 includes an active element such as a transistor, wires such as a bit line and a word line, and the like, which are necessary for the semiconductor chip 10 to function as a DRAM.

Hereinafter, the manufacturing method of the first embodiment is explained. As shown in FIG. 11, the manufacturing method of the first embodiment includes a process S1 of forming the grooves 2; a process S2 of obtaining a reference resistance value; a process S3 of measuring an actual resistance value; a process S4 of calculating a depth of the grooves 2; a process S5 of forming elements; and a process S6 of forming the through electrode 5. Firstly, a process S1 of forming grooves 2 shown in FIG. 11 is carried out.

In the process S1 of forming the grooves 2, a resist film is formed over the semiconductor substrate 1. Then, an exposure and development process is carried out to form a resist layer 7 having a groove pattern having the planar shape of the grooves 2, as shown in FIGS. 1A and 1B.

Then, the semiconductor substrate 1 is dry-etched with the resist layer 7 as a mask to form the grooves 2, as shown in FIGS. 2A and 2B. Each of the grooves 2 has a circular shape in plan view. Each of the grooves 2 has a depth of approximately 50 μm. In other words, the grooves 2 have substantially the same depth. For simplification of explanations, FIGS. 2A and 2B illustrate only a first groove 2a and a second groove 2b among the grooves 2.

The depth of the grooves 2 is controlled by controlling conditions for dry-etching the semiconductor substrate 1. The depth of the grooves 2 defines the vertical thickness of the semiconductor substrate 1 and the depth of the through electrode 5. The depth of the grooves 2 is not limited to a specific value as long as the grooves 2 do not penetrate the semiconductor substrate 1.

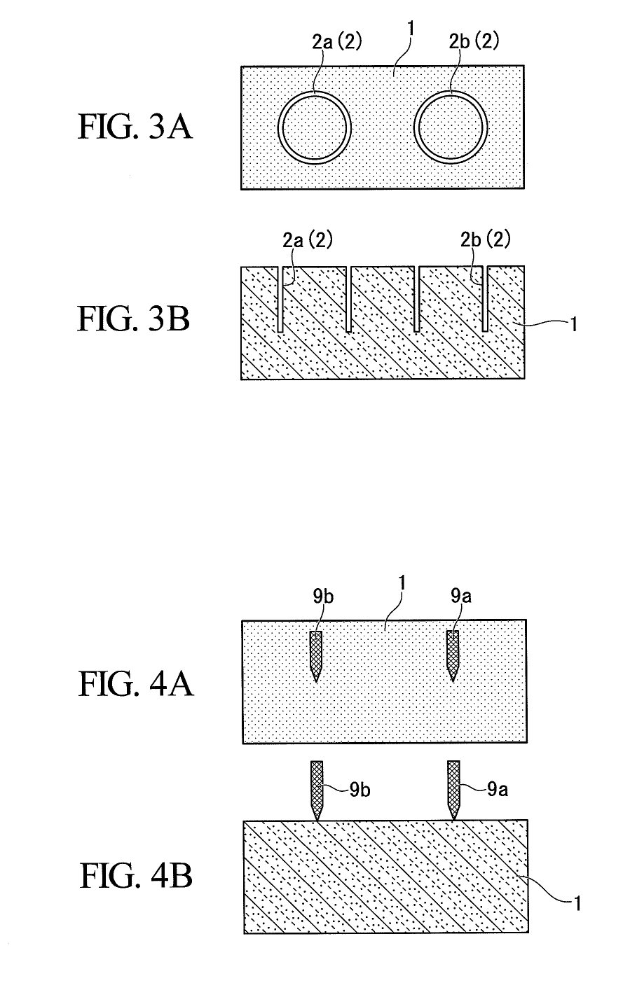

Then, as shown in FIGS. 3A and 3B, the resist layer 7 is removed by an ashing process. The process of removing the resist layer 7 can be initiated quickly after the dry-etching process for forming the grooves 2, in order to achieve high productivity. For this reason, the ashing process is preferably carried out by the same apparatus as the etching apparatus that dry-etches the semiconductor substrate 1, but may be carried out by another apparatus.

In the next process S2 of obtaining a reference resistance value, a pair of probes 9a and 9b of a resistance measuring apparatus is contacted to two points on a surface of the semiconductor substrate 1, as shown in FIGS. 4A and 4B. The two points are positioned outside the grooves 2 in plan view. Thus, a reference resistance value of the semiconductor substrate 1 can be measured.

In the process S2, the pair of the probes 9a and 9b is separated from each other by the same distance as when an actual resistance value is measured, as will be explained later. In the first embodiment, the distance between the probes 9a and 9b is set to be the same as the distance between the centers of the first and second grooves 2a and 2b.

In the next process S3 of measuring an actual resistance value, an actual resistance value between a surface region of the semiconductor substrate 1 surrounded by the first groove 2a in plan view and a surface region of the semiconductor substrate 1 surrounded by the second groove 2b in plan view is measured through a lower portion of the semiconductor substrate 1 which is lower in level than the bottoms of the grooves 2, as shown in FIGS. 5A and 5B.

In this case, the resistance measuring apparatus including the pair of the probes 9a and 9b is used. The probe 9a is contacted to a center of a surface region of the semiconductor substrate 1, which is surrounded by the first groove 2a in plan view. The probe 9b is contacted to a center of a surface region of the semiconductor substrate 1, which is surrounded by the second groove 2b in plan view. Thus, an actual resistance value between the two regions respectively surrounded by the first and second grooves 2 in plan view can be measured precisely, and therefore the depth of the grooves 2 can be calculated precisely.

The surface region of the semiconductor substrate 1, which is surrounded by the groove 2, is a region in which the through electrode 5 is formed in a later process. For this reason, even if the surface region is damaged by inserting the probes 9a and 9b, the functions of the semiconductor chip 10 are not affected thereby.

The resistance measuring apparatus used in the processes S2 and S3 may operate independently (i.e., “stand-alone”). However, the resistance measuring apparatus is preferably included in the etching apparatus that dry-etches the semiconductor substrate 1. When the resistance measuring apparatus is included in the etching apparatus, the processes S2 and/or S3 can be carried out while dry-etching the semiconductor substrate 1 to form the grooves 2, thereby enabling measurement of the depth of the grooves 2 without causing a decrease in the productively.

Preferably, a resistance measurement apparatus using the four probe method is used for the processes S2 and S3. However, a resistance measurement apparatus using another method may be used.

In the next process S4 of calculating the depth of the grooves 2, a case, in which the depth of the grooves 2 is calculated using the difference between the actual resistance value and the reference resistance value, is explained. FIG. 12 is a graph illustrating a relationship between the actual resistance value measured and the depth of the grooves 2. As shown in FIG. 12, a value obtained by subtracting a reference resistance value from an actual resistance value is a value of the resistance of the semiconductor substrate 1 between two portions of the semiconductor substrate 1 which are surrounded by the first and second grooves 2a and 2b, respectively, and is proportional to the depth of the groove 2.

Accordingly, the actual resistance value shown in FIG. 12 depends on the depth of the grooves 2 irrespective of the distance between the pair of the probes 9a and 9b (i.e., between the centers of the first and second grooves 2a and 2b). For this reason, the depth of the grooves 2 can be easily and precisely calculated from the difference between the actual resistance value and the reference resistance value.

Although it has been explained in the process S4 that the difference between the actual and reference resistance values is used to calculate the depth of the grooves 2, the depth of the grooves 2 may be calculated using only the actual resistance value. For example, a relational expression between actual reference values and depths of the grooves 2 is previously obtained and stored by experiments, and then a depth of the groove 2 may be calculated using an actual resistance value and the relational expression.

Preferably, the process S4 includes a process of determining whether or not the depth of the grooves 2 is within a predetermined allowable range. Preferably, only when the depth of the grooves 2 is within the allowable range, the next process S5 is carried out. Thus, a defective semiconductor substrate 1 having grooves 2 whose depths are outside the allowable range can be removed. Accordingly, the process S4 and the following processes do not have to be carried out for the defective semiconductor substrate 1, thereby increasing the productivity.

In the next process S5 of forming elements, the groove 2 is filled with an insulating film to form the circular insulating film 3, as shown in FIG. 6. Then, to make the semiconductor chip 10 function as a DRAM element, multiple elements including an active element such as a transistor, wires such as bit and word lines, and the like are formed over the semiconductor substrate 1. Further, the wire 4 and the bump 6a for electrically coupling the semiconductor chip 10 to an external unit through the through electrode 5 are formed.

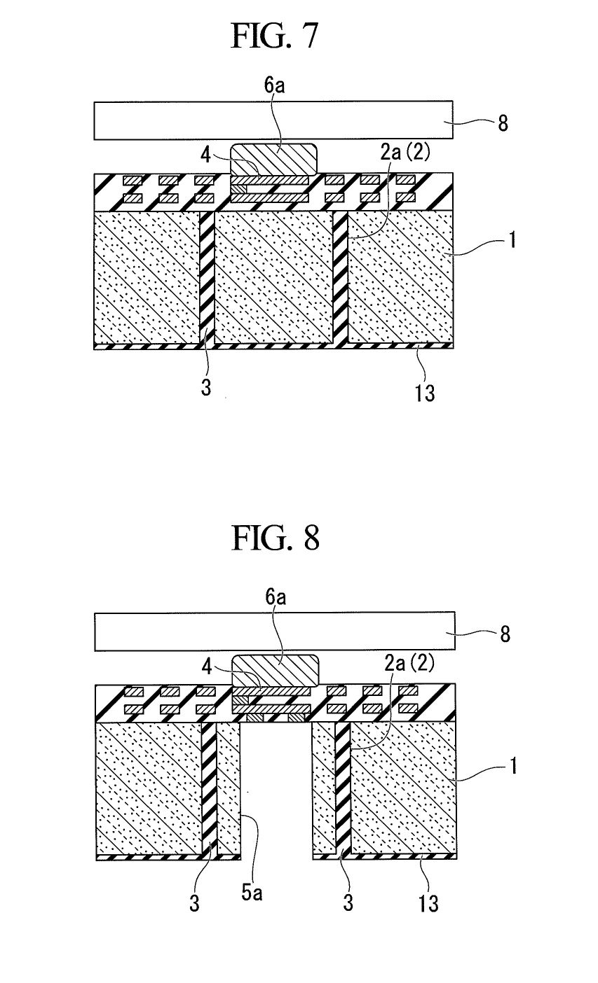

In the next process S6 of forming the through electrode 5, a carrier 8 made of a glass or the like is fixed onto a surface of the semiconductor substrate 1, from which the grooves 2 extend, as shown in FIG. 7. Then, the other surface of the semiconductor substrate 1, from which the grooves 2 do not extend, is polished until the insulating film 3 is exposed. Thus, the semiconductor substrate 1 is decreased in thickness.

Then, an insulating film 13 is formed on the other surface of the semiconductor substrate 1, from which the grooves 2 do not extend. Then, the semiconductor substrate 1 is selectively etched from the other surface thereof to form a contact hole 5a penetrating the semiconductor substrate 1 and exposing the wire 4, as shown in FIG. 8. The contact hole 5a is positioned inside the circular insulating film 3 in plan view.

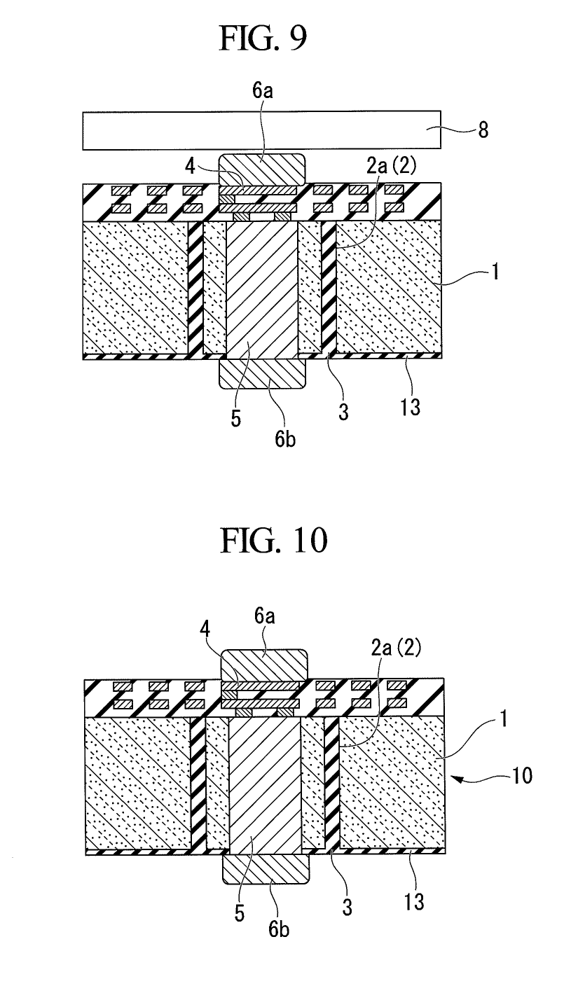

Then, the contact hole 5a is filled with copper by a plating method or the like to form the through electrode 5, as shown in FIG. 9. Then, the bump 6a is formed so as to cover the through electrode 5 from the other surface of the semiconductor substrate 1, from which the grooves 2 do not extend. The bump 6b is used for electrically coupling the semiconductor chip 10 to an external unit.

Then, the carrier 8 is removed as shown in FIG. 10. Thus, the semiconductor chip 10 shown in FIG. 1 can be obtained. Then, a plurality of the semiconductor chips 10, each of which is obtained by the above method, are stacked to form a multi-layered chip. Thus, the semiconductor device of the first embodiment can be obtained.

It has been explained in the first embodiment that the process S2 of obtaining a reference resistance value is carried out before the process S3 of measuring an actual resistance value. However, the process S2 may be carried out after the process S3 as long as the process S2 is carried out before the process S4 of calculating the depth of the grooves 2.

The case, in which a value of the resistance between a surface region of the semiconductor substrate 1 surrounded by the first groove 2a in plan view and a surface region of the semiconductor substrate 1 surrounded by the second groove 2b in plan view is measured through the lower portion of the semiconductor substrate 1 which is lower in level than the bottoms of the first and second grooves 2a and 2b, has been explained in the first embodiment. However, another method of measuring a resistance value may be used.

According to the first embodiment of the present invention, the manufacturing method of the first embodiment includes the aforementioned processes S1 to S4. Accordingly, the depth of the circular grooves 2 having the large depth, the small width, and a curved side surface can be measured easily and non-destructively.

Additionally, in the process S3 of measuring an actual resistance value, the resistance measuring apparatus including the pair of the probes 9a and 9b is used. The probe 9a is contacted to a surface region of the semiconductor substrate 1, which is surrounded by the first groove 2a in plan view. The probe 9b is contacted to a surface region of the semiconductor substrate 1, which is surrounded by the second groove 2b in plan view. Thus, an actual resistance value of the semiconductor substrate between the two regions respectively surrounded by the first and second grooves 2 in plan view can be measured precisely.

Further, the process S2 of obtaining a reference resistance value is carried out before the process S4 of calculating the depth of the groove 2 using the difference between the actual and reference resistance values. In the process S2, the pair of probes 9a and 9b of a resistance measuring apparatus is contacted to two points on a surface of the semiconductor substrate 1, which are positioned outside the grooves 2 in plan view. In this case, the pair of the probes 9a and 9b are separated from each other by the same distance as when an actual resistance value is measured. Accordingly, the depth of the groove 2 can be calculated easily and precisely.

Moreover, the second groove 2b is adjacent to the first groove 2a. Accordingly, the difference between the actual and reference resistance values becomes small, thereby enabling more precise calculation of the depth of the groove 2.

Additionally, the through electrode 5 is made of Cu, and the circular insulating film 3 functions as a barrier film for preventing thermal diffusion. Accordingly, the semiconductor device including the semiconductor chip 10 including the through electrode 5 with excellent reliability and conductivity can be obtained.

Further, the manufacturing method of the first embodiment includes the aforementioned processes S5 and S6. Accordingly, the semiconductor device including the semiconductor chip 10, which can be easily electrically coupled to an external unit when multiple semiconductor chips 10 are stacked, can be obtained.

Moreover, the manufacturing method of the first embodiment includes the process of forming the semiconductor chip 10, and the process of stacking the multiple semiconductor chips 10 to form a multi-layered chip. The process of forming the semiconductor chip 10 includes the aforementioned processes S1 to S6. Accordingly, a high performance semiconductor device including a multi-layered chip can be obtained.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, and may be modified and changed without departing from the scope and spirit of the invention.

For example, it has been explained in the first embodiment that multiple circular grooves 2 are formed in the semiconductor substrate 1, and the depth of the grooves 2 is calculated by measuring a reference resistance value between two points on a surface of the semiconductor substrate 1 which are outside the two grooves 2a and 2b and an actual resistance value between two points on the surface of the semiconductor substrate 1 which are surrounded by the two grooves 2a and 2b, respectively. However, the present invention is applicable to when one circular groove 2 is formed in the semiconductor substrate 1. In this case, two points on a surface of the semiconductor substrate 1 which are outside the groove 2 are set to measure a reference resistance value therebetween. Additionally, other two points on the surface of the semiconductor substrate 1, one of which is inside the groove 2 and the other of which is outside the groove 2, are set to measure an actual resistance value therebetween. Then, the difference between the reference resistance value and the actual resistance value is calculated. Thus, the depth of the one groove 2 can be calculated with reference to the difference.

Further, the planar shape of the groove 2 is not limited to a circle as long as a surface of the semiconductor substrate 1 is divided into two regions by the groove. For example, the present invention is applicable to when one straight groove is formed in the semiconductor substrate 1, and a surface of the semiconductor substrate 1 is divided into two regions by the straight groove. In this case, two points, both of which are positioned on one of the divided regions of the surface of the semiconductor substrate 1, are set to measure a reference resistance value therebetween. Additionally, other two points, one of which is positioned on one of the divided regions and the other one of which is positioned on the other one of the divided regions, are set to measure an actual resistance value therebetween. Then, the difference between the reference resistance value and the actual resistance value is calculated. Thus, the depth of the straight groove can be calculated with reference to the difference.

What is claimed is:

1. A method of manufacturing a semiconductor device, comprising:
forming first and second grooves in a semiconductor substrate having a first surface, the first and second grooves having substantially the same vertical dimension, and the first surface having first and second regions surrounded by the first and second grooves, respectively;
measuring an actual resistance value of the semiconductor substrate between a first point on the first region and a second point on the second region; and
calculating the vertical dimension of the first and second grooves with reference to the actual resistance value.

2. The method according to claim 1, further comprising:
before calculating the vertical dimension, measuring a reference resistance value of the semiconductor substrate between third and fourth points on the first surface of the semiconductor substrate, the third and fourth points being positioned outside the first and second regions; and
calculating a difference between the actual resistance value and the reference resistance value,
wherein calculating the vertical dimension comprises referring to the difference.

3. The method according to claim 2, wherein
measuring the actual resistance value comprises contacting first and second probes of a resistance measuring apparatus to the first and second points, and
measuring the reference resistance value comprises contacting the first and second probes to the third and fourth points.

4. The method according to claim 2, further comprising:
before measuring the reference resistance value, setting the third and fourth points to have a first distance from each other; and
before measuring the actual resistance value, setting the first and second points to have the first distance from each other.

5. The method according to claim 1, further comprising:
after calculating the vertical dimension, forming first and second insulating films filling the first and second grooves, respectively;
forming an active element and a wiring structure over the first surface of the semiconductor substrate; and
forming first and second through electrodes penetrating the semiconductor substrate, the first and second through electrodes being positioned in the first and second regions, respectively.

6. The method according to claim 5, further comprising:
after calculating the vertical dimension, determining whether or not the vertical dimension is within an allowable range,
wherein forming the first and second insulating films, forming the active element and the wiring structure, and forming the first and second through electrodes are performed if the vertical dimension is within the allowable range.

7. The method according to claim 5, further comprises:
repeatedly performing a set of forming the first and second grooves, measuring the actual resistance value, calculating the vertical dimension, forming the first and second insulating films, forming the active element and the wiring structure, and forming the first and second through electrodes to form a stack of a plurality of semiconductor chips each having the same structure.

8. The method according to claim 1, further comprising:
before measuring the actual resistance value, setting the first and second points at first and second center points of the first and second regions, respectively.

9. The method according to claim 1, further comprising:
after calculating the vertical dimension, making a connection between the actual resistance value and the vertical dimension; and
storing the connection.

10. A method of manufacturing a semiconductor device, comprising:
forming at least one groove in a semiconductor substrate having a first surface, the first surface having first and second regions separated from each other by the at least one groove;
measuring a reference resistance value of the semiconductor substrate between first and second points on the first region;
measuring an actual resistance value of the semiconductor substrate between a third point on the first region and a fourth point on the second region;
calculating a difference between the reference resistance value and the actual resistance value; and
calculating a vertical dimension of the at least one groove with reference to the difference.

11. The method according to claim 10, wherein
forming the at least one groove comprises forming first and second grooves in the semiconductor substrate,
the first and second grooves has substantially the same vertical dimension,
the first region is divided into third and fourth regions by the second groove,
the first and second points is positioned on the third region, and
the third and fourth points are positioned on the fourth and second regions, respectively.

12. The method according to claim 10, wherein forming the at least one groove comprises forming first and second grooves in the semiconductor substrate,
the first and second grooves has substantially the same vertical dimension,
the first region is divided into third and fourth regions by the second groove,
the first and second points is positioned on the third region, and
the third and fourth points are positioned on the fourth and second regions, respectively, and
the second and fourth regions are surrounded by the first and second grooves, respectively.

13. The method according to claim 12, further comprising:
before measuring the actual resistance value, setting the third and fourth points at first and second center points of the fourth and second regions, respectively.

14. The method according to claim 10, further comprising:
before measuring the reference resistance value, setting the first and second points to have a first distance from each other; and
before measuring the actual resistance value, setting the third and fourth points to have the first distance from each other.

15. The method according to claim 10, wherein
measuring the reference resistance value comprises contacting first and second probes of a resistance measuring apparatus to the first and second points, and
measuring the actual resistance value comprises contacting the first and second probes to the third and fourth points.

16. A method comprising:
measuring an actual resistance value of a semiconductor substrate between first and second points, the first and second points being positioned on first and second regions of a first surface of the semiconductor substrate, respectively, the first and second regions being surrounded by first and second grooves in the semiconductor substrate, respectively, and the first and second grooves having substantially the same vertical dimension; and
calculating the vertical dimension of the first and second grooves with reference to the actual resistance value.

17. The method according to claim 16, further comprising:
before calculating the vertical dimension, measuring a reference resistance value of the semiconductor substrate between third and fourth points on the first surface of the semiconductor substrate, the third and fourth points being positioned outside the first and second regions; and
calculating a difference between the actual resistance value and the reference resistance value,
wherein calculating the vertical dimension comprises referring to the difference.

18. The method according to claim 17, wherein
measuring the actual resistance value comprises contacting first and second probes of a resistance measuring apparatus to the first and second points, and
measuring the reference resistance value comprises contacting the first and second probes to the third and fourth points.

19. The method according to claim 17, further comprising:
before measuring the reference resistance value, setting the third and fourth points to have a first distance from each other; and
before measuring the actual resistance value, setting the first and second points to have the first distance from each other.

20. The method according to claim 16, further comprising:
before measuring the actual resistance value, setting the first and second points at first and second center points of the first and second regions, respectively.
